(19) United States
(12) Patent Application Publication
(10) Pub. No.: US 2006/0061843 A1
(43) Pub. Date: Mar. 23, 2006

(54) Image filing apparatus

(75) Inventor: Takayuki Sadakuni, Numazu-shi (JP)

Correspondence Address: SoCAL IP LAW GROUP LLP, 310 N. WESTLAKE BLVD. STE 120, WESTLAKE VILLAGE, CA, 91362, US

(73) Assignees: Kabushiki Kaisha Toshiba, Minato-ku (JP); Toshiba Tec Kabushiki Kaisha, Chiyoda-ku (JP)

(21) Appl. No.: 10/945,746

(22) Filed: Sep. 20, 2004

(51) Int. Cl. G03F 3/08

(52) U.S. Cl. 358/523

(57) ABSTRACT

In an image filing process of a multifunctional peripheral 1 as an image filing apparatus, when image data is input in scanning, network printing or facsimile reception, the input image data is converted into various formats, and the image data in various formats is stored in a filing box 15a.

### BACKGROUND OF THE INVENTION

1. Field of the Invention

The present invention relates to an image filing apparatus such as a multifunctional peripheral which realizes an image filing function of filing, e.g., image data read by a scanner or image data received from an external apparatus, and an image filing method used in the image filing apparatus.

2. Description of the Related Art

Recently, there have been made available multifunctional peripherals which realize image filing functions of filing images read by scanners. According to the conventional image filing function, for example, an image is stored as color image data in a filing box when color scanning is carried out, and as monochrome image data therein when monochrome scanning is carried out. Additionally, the image data stored in the filing box can be used for printing, file transfer, and the like.

For example, when color image data obtained by color scanning is stored in the filing box, to print the color image data as a monochrome image, the color image data must be printed as the monochrome image after it has been converted into monochrome image data. In such a case, it takes a long processing time to convert the color image data into the monochrome image data. In other words, when the color image data is converted into the monochrome image data and then printed as the monochrome image, as compared with a case of printing monochrome image data as a monochrome image, there is a problem that a printing process from issuance of a printing start instruction to actual outputting of a printing result is slow.

### BRIEF SUMMARY OF THE INVENTION

Objects of the present invention are to provide an image filing apparatus which can efficiently use image data of filed images for various purposes and achieve a high process speed when the image data of the filed images are output, and an image filing method used in the image filing apparatus.

A first aspect of the present invention is directed to an image filing apparatus which stores image data, comprising an image input section which inputs image data; an image processing section which converts the image data input by the image input section into a plurality of image data of a plurality of different formats; a memory which stores the image data of the plurality of different formats which the image processing section generates from the image data input by the image input section; and a management section which manages the image data of the plurality of different formats stored in the memory as data regarding one image.

A second aspect of the present invention is directed to an image filing method used in an image filing apparatus which stores image data, comprising inputting image data; executing image processing which converts the input image data into a plurality of image data of a plurality of different formats; storing the image data of the plurality of different formats generated from the input image data in a memory by the image processing; and managing the image data of the plurality of different formats stored in the memory as data regarding one image.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF SEVERAL VIEWS OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a block diagram schematically showing a constitution of a multifunctional peripheral as an image filing apparatus;

FIG. 2 is a diagram illustrating inputting/outputting of image data by an image filing function of the multifunctional peripheral;

FIG. 3 is a flowchart showing a processing flow of the image data by the image filing function; and

FIG. 4 is a diagram showing a structural example of management data of the image data stored in a filing box.

### DETAILED DESCRIPTION OF THE INVENTION

Hereinafter, the preferred embodiments of the present invention will be described with reference to the accompanying drawings.

Next, description will be made of a constitution of a multifunctional peripheral (MFP) 1 as an image filing apparatus according to an embodiment of the invention.

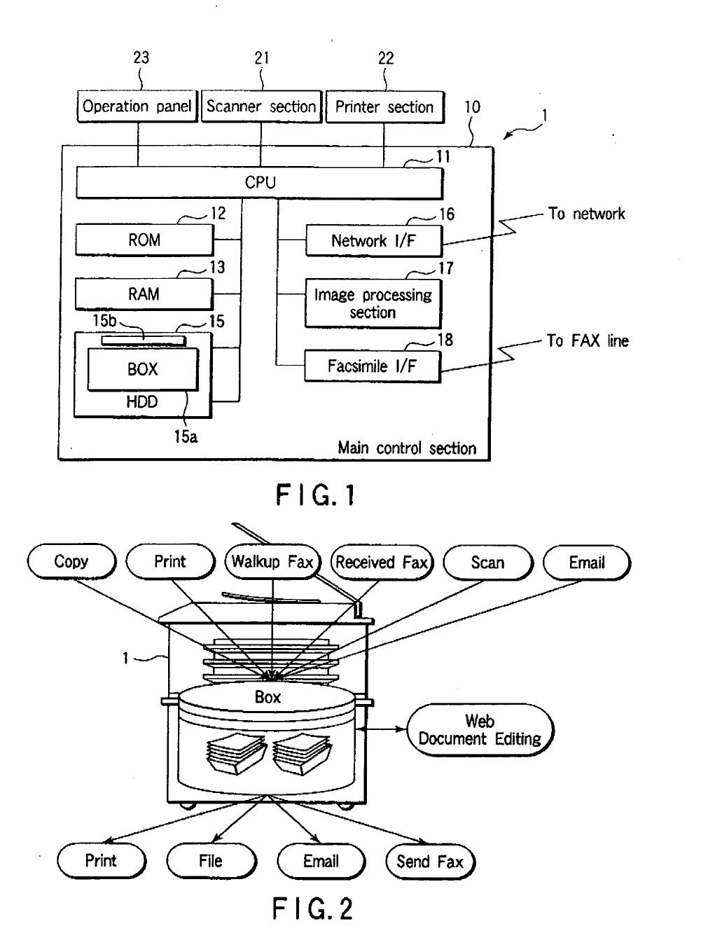

FIG. 1 is a block diagram schematically showing the constitution of the multifunctional peripheral 1.

As shown in FIG. 1, the multifunctional peripheral 1 comprises a main control section 10, a scanner section 21, a printer section 22, an operation panel 23, and the like. The main control section 10 controls the entire multifunctional peripheral 1. The main control section 10 comprises a central processing unit (CPU) 11, a read-only memory (ROM) 12, a random access memory (RAM) 13, a hard disk drive (HDD) 15, a network interface 16, an image processing section 17, a facsimile interface 18, and the like.

The CPU 1 is in overall control of the multifunctional peripheral 1. The ROM 12 stores software such as a control program for controlling the multifunctional peripheral 1. The RAM 13 temporarily stores operation data. The hard disk drive (HDD) 15 is a large-capacity memory.

The HDD 15 comprises a filing box (BOX) 15a and a file database 15b. In the filing box 15a, image data (image files), status data (status files), property data (property files), and the like are stored as files. In the file database 15b, management data of each file in the filing box 15a is stored.

The network interface 16 is an interface for executing data communication with an external apparatus over a network (not shown). The facsimile interface 18 is for exchanging facsimile data with an external apparatus via a FAX line (not shown) or a network (not shown).

The image processing section 17 comprises image processing ASIC, RIP processing sections, image processing middleware, and the like. The image processing section 17 executes color conversion of image data, resolution change thereof, and the like in addition to image processing such as correction, and compression/decompression of the image data. For example, the image processing section 17 converts a color image into a black and white image, a color image into a gray scale image, color image data of RGB into color image data of YMCK, color image data of YMCK into color image data of RGB, and the like. The process by the image processing section 17 will be described in detail later.

The scanner section 21, the printer section 22, the operation panel 23, and the like are connected to the CPU 11. The scanner section 21 optically reads an image of a document, and converts the image into image data. According to the embodiment, the scanner section 21 is a color scanner which reads the document image in color. Additionally, the scanner section 21 reads a color image of RGE (red R, green G, and blue B). The scanner section 21 has a higher resolution higher than at least a printing resolution of the printer section 22.

The printer section 22 prints images on an image forming medium. The printer section 22 prints an image on the image forming medium based on image data read by the scanner section 21 or image data received from an external apparatus. The printer section 22 executes color printing based on color image data of YMCK (yellow Y, magenta M, cyan C, and black K).

The operation panel 23 has a display function of displaying operation guidance to a user, the status of operation setting of the multifunctional peripheral or the like, and an operation function by which an operation instruction is input by the user. For example, the operation panel 23 comprises a touch panel incorporated display, hard keys such as numeric keys, and the like.

Next, the image filing function realized by the multifunctional peripheral I will be described.

FIG. 2 illustrates inputting/outputting of image data by the image filing function of the multifunctional peripheral 1. FIG. 2 shows a concept of the image filing function which the multifunctional peripheral 1 realizes by using the filing box 15a in the HDD 15.

According to the image filing function of the multifunctional peripheral 1, as shown in FIG. 2, the image data is input to the filing box 15a in the case of copying, printing (network printing), scanning, facsimile processing (walk-up FAX processing, FAX reception), electronic mail reception or the like.

For example, when copying of a document image is instructed by means of the operation panel 23, the multifunctional peripheral 1 carries out a copying process of scanning the document image by the scanner section 21 and printing the scanned image by the printer section 22. At the same time, the multifunctional peripheral 1 stores the scanned (copied and scanned) data in the filing box 15a as the image filing function.

When image data for printing is received by the network interface 16 from an external apparatus, the multifunctional peripheral 1 prints the image data received from the external apparatus by the printer section 22 (network printing). At the same time, the multifunctional peripheral 1 stores the image data for printing which has been received from the external apparatus in the filing box 15a as the image filing function.

When scanning of the document image is instructed by means of the operation panel 23, the multifunctional peripheral 1 carries out a scanning process of the document image by the scanner section 21. At the same time, the multifunctional peripheral 1 stores the scanned image data in the filing box 15a as the image filing function.

When facsimile data is received via the facsimile interface 18 from an external apparatus, the multifunctional peripheral 1 prints the facsimile data received from the external apparatus by the printer section 22. At the same time, the multifunctional peripheral 1 stores the received facsimile data in the filing box 15a as the image filing function.

When image data is received as electronic mail via the network interface, the multifunctional peripheral 1 stores the image data of the electronic mail in the filing box 15a as the image filing function.

According to the image filing function of the multifunctional peripheral 1, as shown in FIG. 2, the image data is output from the filing box 15a in the case of printing (network printing), file transfer, electronic mail transmission, facsimile transmission or the like.

For example, when the image data in the filing box 15a is printed, the multifunctional peripheral 1 prints the image data for printing which has been stored as the image data in the filing box 15a on the image forming medium by the printer section 22, and outputs the print.

When the image data in the filing-box 15a is transmitted as electronic mail to an external apparatus, the multifunctional peripheral 1 generates electronic mail to which the electronic mail image data stored as the image data in the filing box 15a is attached, and transmits the electronic mail via the network interface 16 to the external apparatus.

When the image data in the filing box 15a is transmitted as facsimile data to an external apparatus, the multifunctional peripheral 1 transmits the facsimile data as the image data stored in the filing box 15a via the facsimile interface 18 to the external apparatus.

Further, the multifunctional peripheral 1 has a web document editing function as a function of processing image data made public on the World Wide Web via the network. According to the web document editing function, the image data made public on the web is input to/output from the filing box 15a.

As described above, according to the image filing function, the image data scanned by the scanner or the image data received from an external apparatus is stored in the filing box 15a. Moreover, according to the image filing function, the image data in the filing box 15a is output when necessary.

The image data stored in the filing box 15a by the image filing function is preferably in a form suited to a purpose at the time of outputting. This is because conversion into an image data form takes a long processing time. However, when the image data is stored in the filing box 15a, it is difficult to uniquely decide a form of the image data at the time of outputting. Thus, according to the embodiment, image data are stored in various forms (forms according to various purposes) in the filing box 15a.

Next, description will be given of processing of the image data by the image filing function.

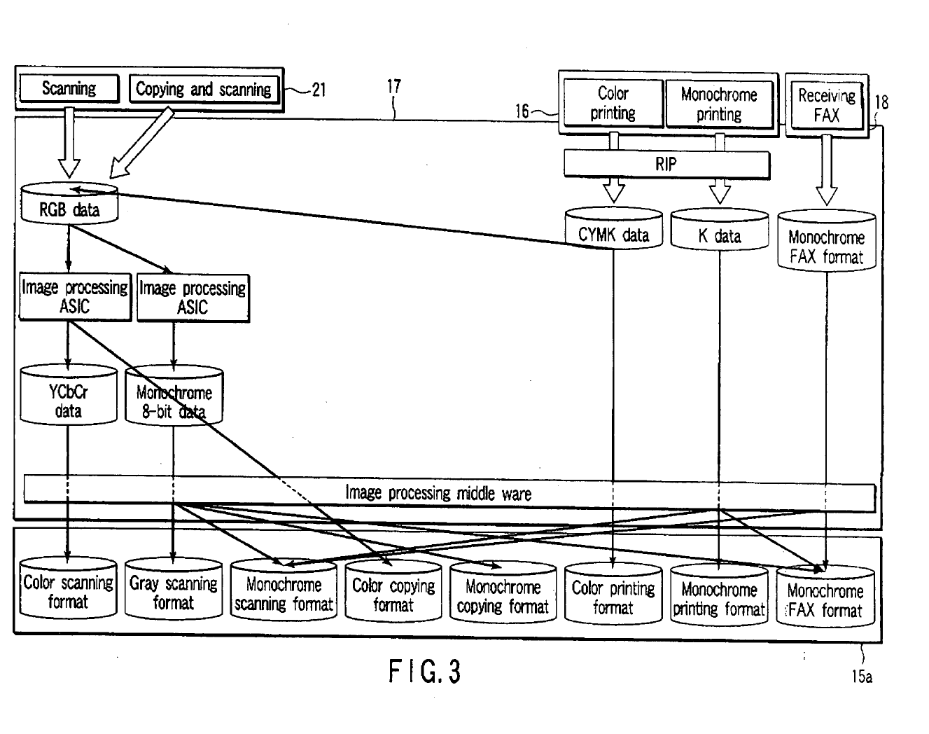

FIG. 3 is a flowchart showing a processing flow of the image data by the image filing function.

First, description will be given of processing of the image data read by the scanning or the image data read in the copying process (copying and scanning).

When a user instructs scanning of the document image by mans of the operation panel 23, the CPU 11 of the main control section 10 reads the document image by the scanner section 21. In this event, the scanner section 21 scans the document image in accordance with a scanning mode (setting of monochrome, color, resolution or the like) which the user instructs by means of the operation panel 23. It is assumed here that the scanner section 21 reads the document image as color image data of RGB (referred to as RGB data) at the highest resolution (e.g., 600 dpi).

After the scanner section 21 has read the document image by the scanning, the CPU 11 of the main control section 10 executes filing for the document image read by the scanner section 21. As shown in FIG. 3, the RGB data read by the scanner section 21 is converted into color image data of a plurality of forms and monochrome image data of a plurality of forms by the image processing ASIC, the image processing middleware, and the like in the image processing section 17, and stored in the filing box 15a.

For example, the scanned RGB data is converted as color image data into a color scanning format and a color copying format. Additionally, the scanned RGB data is converted into a grayscale scanning format, a monochrome scanning format, a monochrome copying format, and a monochrome facsimile format as monochrome image data.

The color scanning format is obtained by converting the scanned RGB data into a predetermined image format (e.g., JPEG). The color copying format is obtained by converting the scanned RGB data into a color printing format by the printer section 22 (e.g., CMYK data of a resolution of the printer section 22).

The grayscale scanning format is obtained by converting the scanned RGB data into a predetermined monochrome image format having a density value (e.g., S-bit JPEG). The monochrome scanning format is obtained by converting the scanned RGB data into a black and white image format (e.g., JSIG). The monochrome copying format is obtained by converting the scanned KGB data into a monochrome printing format by the printer section 22 (e.g., K data of a resolution of the printer section 22). The monochrome facsimile format is obtained by converting the scanned RGB data into a facsimile transmitting format by the facsimile interface 18 (facsimile data).

Furthermore, the image data of the color scanning format, the monochrome scanning format, and the facsimile format are converted into those of a plurality of resolutions, and stored as a plurality of image data of the plurality of resolutions in the filing box 15a. For example, in the case of 600-dpi scanned RGB data, as the color scanning format, the monochrome scanning format and the facsimile format, image data of 200 dpi, of 400 dpi, and of 600 dpi are stored in the filing box 15a.

Next, description will be given of processing of the image data (image data for color printing, or image data for monochrome printing) received in the network printing process.

When the image data for printing is received via the network interface 16 from the network, the CPU 11 of the main control section 10 executes printing based on the received image data, and image filing. Here, description will be given of an image filing process when the image data for color printing or the image data for monochrome printing is received.

When the network interface 16 receives the image data for color printing, the CPU 11 of the main control section 10 executes image filing for the received image data for color printing. In this case, the received image data for color printing is converted into color image data of a plurality of forms and monochrome image data of a plurality of forms by the RIP processing section, the image processing ASIC section, the image processing middleware, and the like in the image processing section 17, and stored in the filing box 15a.

In the constitutional example of FIG. 3, the image data for color printing is converted into color image data (CMYK data) of CMYK (cyan signal C, magenta signal M, yellow signal M, and black signal K) by the RIP processing of the image processing section 17, converted into image data of various forms, and stored in the filing box 15a.

For example, the CMYK data as the image data for color printing is converted into a color printing format and a color copying format as color image data. Additionally, the CMYK data as the image data for color printing is converted into a grayscale scanning format, a monochrome scanning format, a monochrome printing format, and a monochrome facsimile format as monochrome image data.

The color scanning format is obtained by converting the CMYK data into RGB data, and converting the RGB data into a predetermined image format (e.g., JPEG). The color printing format is obtained by converting the CMYK data into a color printing format by the printer section 22 (e.g., CMYK data of a resolution of the printer section 22).

The grayscale scanning format is obtained by converting the CMYK data into RGS data, and converting the RGB data into a predetermined monochrome image format having a density value (e.g., S-bit JPEG). The monochrome scanning format is obtained by converting the CHYK data into RGB data, and converting the RGB data into a black and white image format (e.g., JBIG). The monochrome copying format is obtained by converting the CMYK data into RGB data, and converting the ROB data into a monochrome printing format by the printer section 22 (e.g., K data of a resolution of the printer section 22). The monochrome facsimile format is obtained by converting the CMYK data into RGB data, and converting the RGB data into a facsimile transmitting format by the facsimile interface 18 (facsimile data).

Furthermore, the image data of the color scanning format, the monochrome scanning format, and the facsimile format are converted into those of a plurality of resolutions by the image processing section 17, and stored as a plurality of image data of the plurality of resolutions in the filing box 15a.

When the network interface 16 receives the image data for monochrome printing, the CPU 11 of the main control section 10 executes image filing for the received image data for monochrome printing. In this case, the received image data for monochrome printing is converted into monochrome image data of a plurality of forms by the RIP processing section, the image processing ASIC section, the image processing middleware, and the like in the image processing section 17, and stored in the filing box 15a.

In the constitutional example of FIG. 3, the image data for monochrome printing is converted into monochrome image data (K data) of a K signal by the RIP processing of the image processing section 17, converted into image data of various forms, and stored in the filing box 15a.

For example, the K data as the image data for monochrome printing is converted into a monochrome scanning format, a monochrome printing format and a monochrome facsimile format as monochrome image data.

The monochrome scanning format is obtained by converting the K data into black and white image format (e.g., JBIG). The monochrome printing format is obtained by converting the K data into a monochrome printing format by the printer section 22 (e.g., K data of a resolution of the printer section 22). The monochrome facsimile format is obtained by converting the K data into a facsimile transmitting format by the facsimile interface 18 (facsimile data).

Furthermore, the image data of the monochrome scanning format and the monochrome facsimile format are converted into those of a plurality of resolutions by the image processing section 17, and stored as a plurality of image data of the plurality of resolutions in the filing box 15a.

Next, description will be given of processing of the image data received in the facsimile reception process.

When the facsimile interface 18 receives the facsimile data, the CPU 11 of the main control section 10 executes printing based on image data as the received facsimile data, and image filing for the received facsimile data. In this case, the facsimile data is monochrome image data.

That is, when the facsimile interface 18 receives the monochrome image data as the facsimile data, the CPU 11 of the main control section 10 executes image filing for the received monochrome image data. In the constitutional example of FIG. 3, the facsimile data is converted into monochrome image data of various forms by the image processing middleware or the like of the image processing section 17, and stored in the filing box 15a.

For example, the monochrome image data as the facsimile data is converted into a monochrome scanning format, a monochrome printing format and a monochrome facsimile format.

The monochrome scanning format is obtained by converting the facsimile data into black and white image format (e.g., JBIG). The monochrome printing format is obtained by converting the facsimile data into a monochrome printing format by the printer section 22 (e.g., K data of a resolution of the printer section 22). The monochrome facsimile format is obtained by converting the facsimile data into a facsimile transmitting format by the facsimile interface 18 (facsimile data).

Furthermore, the image data of the monochrome scanning format and the monochrome facsimile format are converted into those of a plurality of resolutions by the image processing section 17, and stored as a plurality of image data of the plurality of resolutions in the filing box 15a.

According to the image filing process, the image data input by scanning, network printing, or facsimile reception is converted into various formats, and the image data of various formats are stored in the filing box 15a.

Incidentally, various formats generated from the image data input by the scanning, copying and scanning, color printing, monochrome printing or facsimile reception may be selected by the user. For example, this is realized in such a manner that the user presets types of formats generated from the image data received by the scanning, color printing, monochrome printing or facsimile reception. Additionally, the user may specify formats to be generated for each of the scanning, copying and scanning, color printing, monochrome printing or facsimile reception.

Furthermore, the process of converting the input image data into various formats may be carried out at a time set by the user. For example, by setting a time zone for executing conversion into formats to a low operation rate time of the multifunctional peripheral 1 such as midnight, it is possible to efficiently convert the image data into formats.

Next, description will be given of management of the image data stored in the filing box 15a by the image filing function.

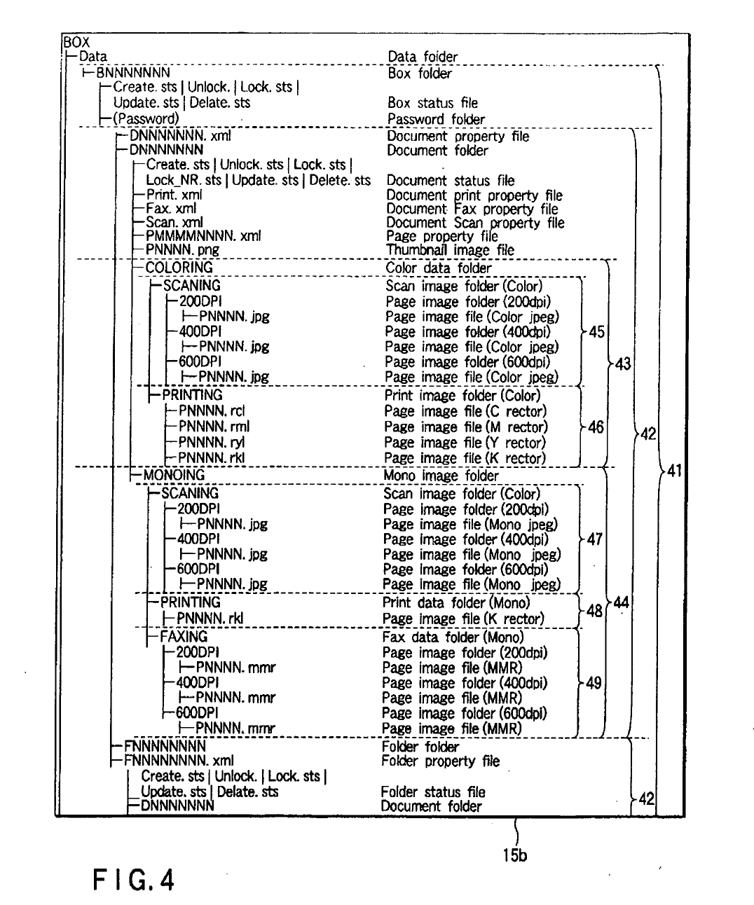

FIG. 4 is a diagram showing a structural example of management data of the image data stored in the filing box 15a.

In the example shown in FIG. 4, the image data of various forms stored in the filing box 15a are managed in a hierarchical structure. The management data for managing the image data or the like in the filing box 15a is stored in the file database 15b,

As shown in FIG-4, the filing box 15a is managed by a box folder 40. For example, when a filing box 15a is disposed for each user, the filing box 15a of each user is managed by a box folder 41.

In the box folder 41, as information for managing the box folder, there are a box status file indicating the status of the filing boxes and a password folder of encrypted passwords for accessing the filing boxes. The passwords stored in the password file are set when access to each filing box 15a is limited to a specific user.

There are a document property file and a document folder below the box status file and the password folder. A document comprises a group of images (images of a plurality of pages). The embodiment will be described by assuming that a document comprises one image. The document property file indicates document management information for showing contents of a document as an image. The document folder is for managing various data regarding an image (document).

In the document folder 42, there are a document status file, a document print property file, a document scan property file, a document facsimile property file, a page property file, a thumbnail image file, a color image folder (COLORING) 43, and a monochrome image folder (MONOING) 44.

The document status file holds information indicating the document status. The document print property file holds information for printing the document. The document scan property file holds information for transferring the document as a file to an external apparatus such as a PC. The document facsimile property file holds information for transmitting the document by fax. The page property file holds information regarding the size or the like of each image constituting the document. The thumbnail image file holds image data for displaying the document as thumbnails.

In the color image folder 43, there are a scan image folder (SCANNING) 45 and a print image folder (PRINTING) 46.

In the scan image folder 45, image data of a color scanning format is managed as an image file. Further, in the scan image folder 45, image data of a color scanning format of each resolution (200 dpi, 400 dpi, or 600 dpi) is managed.

In the print image folder 46, image data of a color copying format (or color printing format) is managed as an image file. Incidentally, in the example shown in FIG. 4, in the print image folder 46, cyan image data (C vector), magenta image data (M vector), yellow image data (Y vector), and black image data (K vector) are managed as image data of color copying formats (or color printing formats).

In the monochrome image folder 44, there are a scan image folder (SCANNING) 47, a print image folder (PRINTING) 48, and a facsimile image folder (FAXING) 49.

In the scan image folder 47, image data of a monochrome scanning format or image data of a grayscale scanning format is managed as an image file. Further, in the scan image folder 47, image data of a monochrome scanning format (or grayscale scanning format) of each resolution (200 dpi, 400 dpi, or 600 dpi) is managed.

In the print image folder 48, image data of a monochrome copying format (or monochrome printing format) is managed as an image file. Incidentally, in the example shown in FIG. 4, in the print image folder 48, black image data (K vector) is managed as image data of a monochrome copying format (or monochrome printing format).

In the facsimile image folder 49, image data of a monochrome facsimile format is managed as an image file. Further, in the facsimile image folder 49, image data of monochrome facsimile formats of a plurality of resolutions (200 dpi, 400 dpi, and 600 dpi) are managed.

According to the aforementioned management structure, it is possible to easily manage image data of various formats stored in the filing box 15a.

As described above, in the image filing process of the multifunctional peripheral 1, the input image data is converted into various formats when the image data is input in scanning, network printing, or facsimile reception, and image data of various formats are stored in the filing box 15a. Thus, image data suited to a purpose of use can be immediately output from the filing box 15a.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

1. An image filing apparatus which stores image data, comprising:
an image input section which inputs image data;
an image processing section which converts the image data input by the image input section into a plurality of image data of a plurality of different formats;
a memory which stores the image data of the plurality of different formats which the image processing section generates from the image data input by the image input section; and
a management section which manages the image data of the plurality of different formats stored in the memory as data regarding one image.

2. The image filing apparatus according to claim 1, wherein when the image input by the image input section is color image data, the image processing section converts the color image data input by the image input section into monochrome image data, the memory stores the color image data and the monochrome image data, and the management section manages the color image data and the monochrome image data stored in the memory as data regarding one image.

3. The image filing apparatus according to claim 1, wherein when the image input by the image input section is color image data, the image processing section converts color signals of the color image data input by the image input section into color image data of different color signals, the memory stores the plurality of color image data of the different color signals, and the management section manages the plurality of color image data of the different color signals stored in the memory as data regarding one image.

4. The image filing apparatus according to claim 1, wherein the image processing section converts the image data input by the image input section into a plurality of image data of different resolutions, the memory stores the plurality of image data of the different resolutions, and the management section manages the plurality of image data of the different resolutions stored in the memory as data regarding one image.

5. The image filing apparatus according to claim 1, wherein the plurality of different formats generated by the image processing section include an image format suited to printing.

6. The image filing apparatus according to claim 1, wherein the plurality of different formats generated by the image processing section include an image format suited to transfer of image data as a file.

7. The image filing apparatus according to claim 1, wherein the plurality of different formats generated by the image processing section include an image format suited to facsimile transmission.

8. The image filing apparatus according to claim 1, wherein the plurality of different formats generated by the image processing section include an image format suited to transmission of image data by electronic mail.

9. The image filing apparatus according to claim 1, wherein the image input section is a scanner.

10. The image filing apparatus according to claim 1, wherein the image input section is an interface which receives image data from an external apparatus.

11. An image filing method used in an image filing apparatus which stores image data, comprising:
inputting image data;
executing image processing which converts the input image data into a plurality of image data of a plurality of different formats;
storing the image data of the plurality of different formats generated from the input image data in a memory by the image processing; and
managing the image data of the plurality of different formats stored in the memory as data regarding one image.

12. The method according to claim 11, wherein when the input image is color image data, in the image processing, the input color image data is converted into monochrome image data; in the storing, the color image data and the monochrome image data are stored in the memory; and in the managing, the color image data and the monochrome image data stored in the memory are managed as data regarding one image.

13. The method according to claim 11, wherein when the input image is color image data, in the image processing, color signals of the input color image data are converted into color image data of different color signals; in the storing, the plurality of color image data of the different color signals are stored in the memory; and in the managing, the plurality of color image data of the different color signals stored in the memory are managed as data regarding one image.

14. The method according to claim 11, wherein in the image processing, the input image data is converted into a plurality of image data of different resolutions; in the storing, the plurality of image data of the different resolutions are stored in the memory; and in the managing, the plurality of image data of the different resolutions stored in the memory are managed as data regarding one image.

15. The method according to claim 11, wherein the plurality of different formats generated in the image processing include an image format suited to printing.

16. The method according to claim 11, wherein the plurality of different formats generated in the image processing include an image format suited to transfer of image data as a file.

17. The method according to claim 11, wherein the plurality of different formats generated in the image processing include an image format suited to facsimile transmission.

18. The method according to claim 11, wherein the plurality of different formats generated in the image processing include an image format suited to transmission of image data by electronic mail.

19. The method according to claim 11, wherein in the inputting of the image data, the image data is input as image data of a document image read by a scanner.

20. The method according to claim 11, wherein in the inputting of the image data, image data received from an external apparatus via an interface is input.

21. A process comprising:
a multifunction peripheral automatically and as an integrated process converting a first image data into a plurality of image data each having a different format, wherein the multifunction peripheral comprises a copier, a scanner, a network interface and a storage medium.

22. The process of claim 21 further comprising:
the multifunction peripheral storing the first image data in the storage medium
the multifunction peripheral storing the plurality of image data in the storage medium, wherein the plurality of image data is associated with the first image data.

23. The process of claim 21 further comprising:
the multifunction peripheral receiving an input identifying a predetermined time to commence the converting step
the multifunction peripheral commencing the converting step at the predetermined time.

24. The process of claim 21 wherein the first image data is color image data and the different formats are selected from the group comprising a color printing format, a plurality of color scanning formats each having a different resolution, a color copying format, a grayscale scanning format, a plurality of monochrome scanning formats each having a different resolution, a monochrome copying format and a plurality of monochrome facsimile formats each having a different resolution.

25. The process of claim 24 wherein the different resolutions are selected from the group comprising 200 dpi, 400 dpi and 600 dpi.

26. The process of claim 24 further comprising:
the multifunction peripheral receiving a selection of different formats for the converting prior to the converting,

27. The process of claim 26 further comprising:
the multifunction peripheral receiving an input identifying a predetermined time to commence the converting step
the multifunction peripheral storing the first image data in the storage medium
the multifunction peripheral commencing the converting step at the predetermined time
the multifunction peripheral storing the plurality of image data in the storage medium, wherein the plurality of image data is associated with the first image data.

28. The process of claim 21 wherein the first image data is monochrome image data and the different formats are selected from the group comprising a plurality of monochrome scanning formats each having a different resolution, a monochrome printing format and a plurality of monochrome facsimile formats each having a different resolution.

29. The process of claim 28 wherein the different resolutions are selected from the group comprising 200 dpi, 400 dpi and 600 dpi.

30. The process of claim 28 further comprising:
the multifunction peripheral receiving a selection of different formats for the converting prior to the converting.

31. The process of claim 30 further comprising:
the multifunction peripheral receiving an input identifying a predetermined time to commence the converting step
the multifunction peripheral storing the first image data in the storage medium
the multifunction peripheral commencing the converting step at the predetermined time
the multifunction peripheral storing the plurality of image data in the storage medium, wherein the plurality of image data is associated with the first image data.

32. A multifunction peripheral comprising,
a copier
a scanner
a network interface
a processor
a memory coupled with the processor
a storage medium having instructions stored thereon which when executed cause the multifunction peripheral to perform actions comprising
automatically and as an integrated process converting a first image data into a plurality of image data each having a different format.

33. The multifunction peripheral of claim 32 wherein the storage medium has instructions stored thereon which when executed cause the multifunction peripheral to perform actions further comprising:
storing the first image data in the storage medium
storing the plurality of image data in the storage medium, wherein the plurality of image data is associated with the first image data.

34. The multifunction peripheral of claim 32 wherein the storage medium has instructions stored thereon which when executed cause the multifunction peripheral to perform actions further comprising:
receiving an input identifying a predetermined time to commence the converting step commencing the converting step at the predetermined time.

35. The multifunction peripheral of claim 32 wherein the first image data is color image data and the different formats are selected from the group comprising a color printing format, a plurality of color scanning formats each having a different resolution, a color copying format, a grayscale scanning format, a plurality of monochrome scanning formats each having a different resolution, a monochrome copying format and a plurality of monochrome facsimile formats each having a different resolution.

36. The multifunction peripheral of claim 35 wherein the different resolutions are selected from the group comprising 200 dpi, 400 dpi and 600 dpi.

37. The multifunction peripheral of claim 35 wherein the storage medium has instructions stored thereon which when executed cause the multifunction peripheral to perform actions further comprising:
receiving a selection of different formats for the converting prior to the converting.

38. The multifunction peripheral of claim 37 wherein the storage medium has instructions stored thereon which when executed cause the multifunction peripheral to perform actions further comprising:
receiving an input identifying a predetermined time to commence the converting step
storing the first image data in the storage medium
commencing the converting step at the predetermined time
storing the plurality of image data in the storage medium, wherein the plurality of image data is associated with the first image data.

39. The multifunction peripheral of claim 32 wherein the first image data is monochrome image data and the different formats are selected from the group comprising a plurality of monochrome scanning formats each having a different resolution, a monochrome printing format and a plurality of monochrome facsimile formats each having a different resolution.

40. The multifunction peripheral of claim 39 wherein the different resolutions are selected from the group comprising 200 dpi, 400 dpi and 600 dpi.

41. The multifunction peripheral of claim 39 wherein the storage medium has instructions stored thereon which when executed cause the multifunction peripheral to perform actions further comprising:
receiving a selection of different formats for the converting prior to the converting.

42. The multifunction peripheral of claim 41 wherein the storage medium has instructions stored thereon which when executed cause the multifunction peripheral to perform actions further comprising:
receiving an input identifying a predetermined time to commence the converting step
storing the first image data in the storage medium
commencing the converting step at the predetermined time
storing the plurality of image data in the storage medium, wherein the plurality of image data is associated with the first image data.
